(19) United States
(12) Patent Application Publication
(10) Pub. No.: US 2005/0262403 A1
(43) Pub. Date: Nov. 24, 2005

(54) Apparatus and method for single operation read-modify-write in a bit-accessible memory unit memory

(76) Inventor: Alexandre Palus, Houston, TX (US)

Correspondence Address: TEXAS INSTRUMENTS INCORPORATED, P O BOX 655474, M/S 3999, DALLAS, TX, 75265, US

(21) Appl. No.: 11/133,952

(22) Filed: May 20, 2005

Related U.S. Application Data
(60) Provisional application No. 60/573,537, filed on May 21, 2004.

(51) Int. Cl. G11C 29/00; G01R 31/28

(52) U.S. Cl. 714/710

(57) ABSTRACT

In a bit-accessible memory, a read-modify-write instruction is replaced by an operation with a single memory access. A first mirror memory is identified by a first address OFFSET of the actual memory address. A SET signal logic process is performed when the first mirror memory is addressed. A second mirror memory is identified by a second address offset. A CLEAR signal logic process is performed when the second address offset is used. Transferring the mask used for the read-modify-write operation along with the address, a single predetermined memory location is enabled. The write data bus has logic “1”s applied to all conductors for a SET operation and all logic “0”s for the Clear operation. Only the predetermined memory location is enabled. Thus the correct logic signal is stored in the only enabled location, the predetermined location identified by the mask. In the absence of the OFFSET signal, a normal write operation is performed for the memory access.

This application claims priority under 35 USC §119(e)(1) of Provisional Application Ser. No. 60/573,537 (TI-38457PS) filed on May 21, 2004.

### BACKGROUND OF THE INVENTION

1. Field of the Invention

This invention relates generally to read-modify-write procedure in a data processing system and, more particularly, to a read-modify-write operation involving a bit-accessible memory unit.

2. Background of the Invention

In data processing system, the modification of a logic signal stored in a memory unit location is frequently required by an executing program. The typical technique to accomplish this operation is called the read-modify-write operation/instruction. In the read-modify-write operation/instruction, a group of data signals, such as a word, is read from a memory unit, the group of data signals including the data signal to be modified. The number of signals in a signal group read from the memory unit is determined by the processing unit. Typically, the size of the signal group transferred from between the processor unit and the memory can have a selectable length, such a byte, word, double word, etc. The data bus for transferring the data between the processor unit and the memory unit will typically be wide enough to accommodate the largest group of logic signals. After reading (retrieving) the signal group including the logic bit to be altered, the logic bit to be modified is modified by the processor by masking and arithmetic operations. The resulting signal group is then written (stored) in the location from which the signal group was read.

Because the read-modify-write operation/instruction is typically a group of three instructions, external processing requirements, such as an interrupt procedure, can disrupt the read-modify-write instruction/operation. The processing system then requires relatively complex procedures that the read-modify-write instruction is not compromised. In addition, the read-modify-write instruction results in additional traffic with respect to the logic signals transferred between the processor unit and the memory unit.

In the following discussion, when the logic signal to be stored at a predetermined memory location is a logic “1” signal, this logic signal will be referred to as a SET signal. When the logic signal to be stored in the predetermined location is a logic “0”, this signal will be referred to as a CLEAR signal.

Even though the typical exchange of data signals between the processor unit and the memory may consist of a multiplicity of logic signals, the memory unit may be bit-accessible. The present invention incorporates a bit accessible memory.

A need has therefore been felt for apparatus and an associated method having the feature of improved operation for a read-modify-write instruction in a processing system having a bit-accessible memory. It is a further feature of the apparatus and associated method to perform a read-modify-write operation in a single cycle of the processing unit. It is yet a still further feature of the apparatus and associated method to store a selected logic signal at a predetermined memory location.

### SUMMARY OF THE INVENTION

The foregoing and other features are accomplished, according the present invention, by providing, in addition to the usual address and data paths between a memory unit and a processing unit, a write enable multiplexer that can enable a predetermined memory location in a bit-accessible memory. When no OFFSET signal group is provided in the address signal group, a normal storage of a data signal group into an addressed group of memory locations is implemented. The presence of a first address OFFSET signal group results in a storage of a SET (logic “1”) signal into a predetermined location, while the presence of a second OFFSET signal group in the address signal group indicates that CLEAR (logic “0”) signal is stored in the predetermined location. The predetermined location is determined by address of the signal group including the predetermined location and a mask signal group specifying the position in the signal group of the predetermined location.

Other features and advantages of the present invention will be more clearly understood upon reading of the following description and the accompanying drawings and the claims.

### BRIEF DESCRIPTION OF THE DRAWINGS

FIG. 1 is block diagram of the apparatus for storing a selected signal at a predetermined location according to the present invention.

FIG. 2 illustrates the concept of a mirror memory in accordance with the present invention.

### DESCRIPTION OF THE PREFERRED EMBODIMENT

1. Detailed Description of the Figures

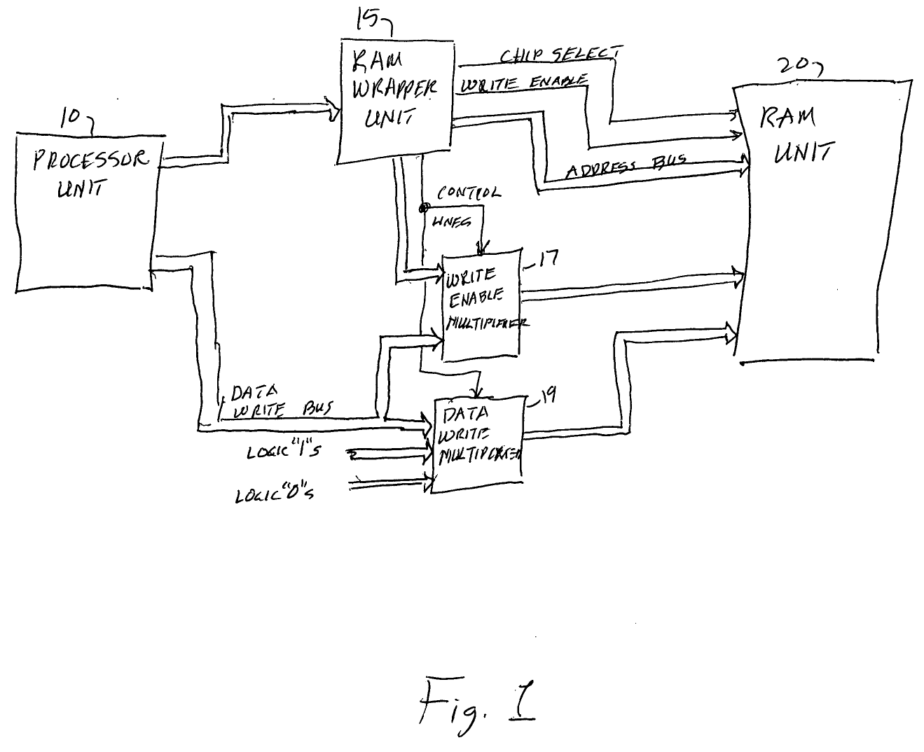

Referring to FIG. 1, the apparatus for implementing the read-modify-write operation with a single memory access is illustrated. Processor unit 10 applies address signals along with signals identifying the size of the data group to the RAM wrapper unit 15. Processor unit 10 applies signals to a data bus. The data bus, in turn, applies signals to a first input port of the data write multiplexer 19 and to first input port of the write enable multiplexer 17. The RAM wrapper unit 15 applies chip select signals, write enable signals, and address bus signals to the RAM unit 20. The RAM wrapper unit 15 applies control signals to the write enable multiplexer 17 and to the data write multiplexer. The RAM wrapper unit 15 applies data group signal to a second port of the write enable multiplexer. A data bus with all logic “1” signals is applied to a second input port of data write multiplexer 19. A data bus with all logic “0” signals is applied to a third input port of data write multiplexer 19. The output signals of write enable multiplexer 17 provides the enable signals to the individual storage locations in the RAM unit 20, while the output signals of the data write multiplexer 19 applies the signal to be stored at the individual addressed location to the RAM memory unit 20.

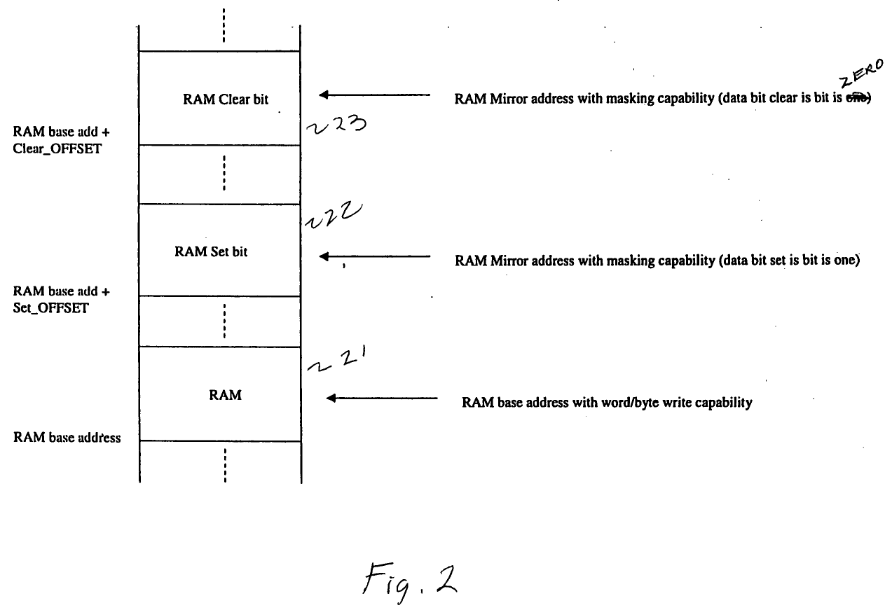

Referring to FIG. 2, the mirror memory concept is illustrated. When the RAM base address is applied to the RAM wrapper 15, the normal write addressing mode for addressing the RAM unit at a given address in memory 21 is indicated. When the address transmitted to the RAM wrapper 15 is the RAM base address+a SET_OFFSET, the write addressing mode for addressing a location in memory 22 is indicated. When the address transmitted to the RAM wrapper unit 15 is a base address+a CLEAR_OFFSET, the write addressing mode for addressing a location in memory 23 is indicated.

2. Operation of the Preferred Embodiment

In normal operation, when data is transferred between the processor unit and the memory unit, the base address of the data group or subgroup is transferred to the RAM wrapper unit. The RAM wrapper applies signals to the write enable that provide enable signals for the data group or subgroup identified by the address signals. These enable signals are selected by the control signals from the RAM wrapper unit. The actual data signal group or subgroup is applied to the data write bus, transmitted through the first port of multiplexer 19 and applied to the memory unit. The first port is selected by the control signals from the RAM wrapper unit. As will be clear, only those data signals that are to be stored (written) in the memory unit will be enabled by the write enable multiplexer and signals on other portions of the data write bus are not stored.

When the read-modify-write operation is to be performed, no data is read from the memory unit 20. Instead, the processor unit forwards an address of the memory locations that includes the predetermined memory location to be altered along with either the CLEAR_OFFSET or the SET_OFFSET. The presence of the SET_OFF in the addresses enables the second port of the data write multiplexer thereby applying logic “1”s to every addressed location in the memory unit. The presence of the CLEAR_OFFSET in the address applied to the memory unit results in the third port of multiplexer 19 being enabled and all logic “0”s being applied to the addressed memory locations. The mask that would be used by the processor unit for changing a selected bit is applied to the appropriate data write bus conductors. The presence of either of the OFFSET addresses causes the RAM wrapper unit to provide control signals enabling the second port of the write enable multiplexer. The mask is applied to the addressed memory unit locations, but the only write enable bit is applied only to the predetermined memory location. The enabled (second or third) port of the multiplexer determines whether a logic “1” or a logic “0” is to be stored at the location determined by the mask.

In this manner, the processor unit is able to change the logic bit at a predetermined location with a single processor unit memory access. The processor unit provides an OFFSET signal in the address signal group that permits the RAM wrapper unit to determine whether a normal write operation, a SET operation, or a CLEAR operation is to be performed. Having identified the operation, the ports of the multiplexer unit can be set accordingly. In a normal write operation, the logic signals on the data write bus are applied to the memory unit. In either the SET or Clear operation, the mask is applied to the write enable multiplexer and a signal enable signal for enabling the predetermined memory location is transmitted. The presence of the SET_ or CLEAR_OFFSET signal determines which port of the data write multiplexer is enabled and whether a logic “1” or a logic “0” will be stored in the predetermined location.

The invention can be generalized in several ways. The write enable multiplexer and the data write multiplexer can be controlled from signals applied directly to the multiplexers by the processor unit, thereby eliminating the involvement of this RAM wrapper unit in the generation of these control signals.

While the invention has been described with respect to the embodiments set forth above, the invention is not necessarily limited to these embodiments. Accordingly, other embodiments, variations, and improvements not described herein are not necessarily excluded from the scope of the invention, the scope of the invention being defined by the following claims.

1. A data processing system, the system comprising:
a processor unit;
a bit-accessible memory unit;
a data write device, the data write device selecting data signal groups for application to the memory unit in response to control signals, a data signal group resulting from a normal write operation of the processor unit being applied to the memory unit, a signal group consisting of all logic “1”s applied to the memory unit in response to a first control signal, a signal group consisting of all logic “0”s applied to the memory unit in response to a second control signal; and
a write enable device, the write enable device responsive to control signals and to bit identification signal group, the write enable device enabling memory locations identified by an address generated by the normal write operation, the write enable device enabling a single memory location identified by the bit identification signal group mask in response to the first and second control signals.

2. The system as recited in claim 1 wherein the bit identification signal group is the mask used in a read-modify-write instruction.

3. The system as recited in claim 2 wherein a read-modify-write operation can be performed by a single memory unit access.

4. The system as recited in claim 1 wherein the first control signal results in the application of all logic “1”s being applied to the memory unit by the data write bus, the second control signal resulting in the application of all logic “0”s to the memory unit by data write bus.

5. The system as recited in claim 1 wherein the control signals are generated by the processor unit as part of the address.

6. The system as recited in claim 1 wherein the data write device and the write enable device are multiplexers.

7. The system as recited in claim 1 further comprising a RAM wrapper unit, the RAM wrapper unit controlling the operation of the data write bit device and the write enable device in response to address enable signals from the processor unit.

8. The system as recited in claim 1 wherein more than one memory location can have preselected logic signal stored in predetermined memory unit locations.

9. A method for performing a write of a selected logic signal in a predetermined memory unit location of a bit-accessible memory unit, the method comprising:
identifying the position of the predetermined memory location;
using the position of the predetermined memory location to provide an write enable signal for only the predetermined memory location; and
applying the selected logic signal to all conductors the data write bus in response to a control signal.

10. The method as recited in claim 9 wherein identifying the predetermined memory location includes generating a mask.

11. The method as recited in claim 10 wherein the write of a selected logic signal in a predetermined memory unit location in the result of executing a read-modify-write instruction.

12. The method as recited in claim 9 further including selecting the logic signal applied to conductors of the data write bus in response to control signals from the processing unit.

13. The method as recited in claim 12 further including providing the control signals in response to an address signal group OFFSET.

14. The method as recited in claim 9 further comprising implementing normal data write to the memory unit when no control signals are generated.

15. The method as recited in claim 14 further including implementing the selection of the data signals applied to the memory unit on the data write bus with a multiplexer.

16. The method as recited in claim 9 further including implementing the memory unit with a RAM unit, the RAM unit including RAM wrapper unit, the RAM wrapper unit receiving address signals from a processor unit, the RAM wrapper unit generating the control signals in response to the address signals.
